(19) United States
(12) Patent Application Publication
(10) Pub. No.: US 2024/0421556 A1
(43) Pub. Date: Dec. 19, 2024

(54) SEMICONDUCTOR PACKAGE AND SEMICONDUCTOR APPARATUS

(71) Applicant: KYOCERA Corporation, Kyoto-shi, Kyoto (JP)

(72) Inventors: Hironobu FUJIWARA, Higashiomi-shi (JP); Takeo SATAKE, Higashiomi-shi (JP)

(73) Assignee: KYOCERA Corporation, Kyoto-shi, Kyoto (JP)

(21) Appl. No.: 18/704,766

(22) PCT Filed: Oct. 27, 2022
(86) PCT No.: PCT/JP2022/040205

§ 371 Date: Apr. 25, 2024

(30) Foreign Application Priority Data
Oct. 28, 2021 (JP) 2021-176646

(51) Int. Cl. H01S 5/02315; H01L 31/0203; H01L 31/0232; H01S 5/02218; H01S 5/0225

(52) U.S. Cl. CPC H01S 5/02315; H01L 31/0203; H01L 31/02325; H01S 5/02218; H01S 5/0225

(57) ABSTRACT

A semiconductor package includes a body, a fixing member, and a bond joining the body and the fixing member. The body includes a base and a frame including an inner side surface, an outer side surface, and an opening portion extending through the frame in a first direction. The fixing member includes a first portion located in the opening portion, a second portion continuous with the first portion and located on the outer side surface of the first portion, and a through-hole extending through the first portion and the second portion in the first direction. The bond is located between the first portion and the opening portion. The opening portion at least partially includes a first linear portion. The first portion includes a second linear portion facing the first linear portion. The bond has a smallest thickness between the first linear portion and the second linear portion.

### TECHNICAL FIELD

The present disclosure relates to a semiconductor package in which a semiconductor device is mountable, and a semiconductor apparatus including a semiconductor device mounted in the semiconductor package.

### BACKGROUND OF INVENTION

A known semiconductor package and a known semiconductor apparatus are described in, for example, Patent Literature 1.

### CITATION LIST

### Patent Literature

Patent Literature 1: Japanese Unexamined Patent Application Publication No. 2002-228888

### SUMMARY

In one embodiment of the present disclosure, a semiconductor package includes a body, a fixing member, and a bond joining the body and the fixing member. The body includes a base including a first upper surface and a frame located on the first upper surface and including an inner side surface, an outer side surface, and an opening portion extending through the frame in a first direction from the outer side surface to the inner side surface. The fixing member includes a first portion located in the opening portion, a second portion continuous with the first portion and located on the outer side surface of the first portion, and a through-hole extending through the first portion and the second portion in the first direction. The bond is located between the first portion and the opening portion. In a cross-sectional view taken along a plane intersecting with the first direction, the opening portion at least partially includes a first linear portion. The first portion includes a second linear portion facing the first linear portion. The bond has a smallest thickness between the first linear portion and the second linear portion in a cross-sectional view taken along a plane intersecting with the first direction.

In one embodiment of the present disclosure, a semiconductor apparatus includes the semiconductor package described above, and a semiconductor device mounted on the first upper surface.

### BRIEF DESCRIPTION OF THE DRAWINGS

The objects, features, and advantages of the present disclosure will become more apparent from the following detailed description and the drawings.

FIG. 1 is an external perspective view of a semiconductor package and a semiconductor apparatus according to one embodiment of the present disclosure.

FIG. 2 is an exploded perspective view of the semiconductor package and the semiconductor apparatus illustrated in FIG. 1.

FIG. 3 is a perspective view of the semiconductor package illustrated in FIG. 1.

FIG. 4 is a plan view of the semiconductor package illustrated in FIG. 1.

FIG. 5 is a perspective view of a body in the semiconductor package illustrated in FIG. 1.

FIG. 6 is a cross-sectional view of the semiconductor package taken along line X1-X1 in FIG. 3.

FIG. 7 is a cross-sectional view of the semiconductor package taken along line Y1-Y1 in FIG. 3.

FIG. 8A is a perspective view of a fixing member in the semiconductor package illustrated in FIG. 1.

FIG. 8B is a rear perspective view of the fixing member illustrated in FIG. 8A.

FIG. 8C is a cross-sectional view taken along line Y2-Y2 in FIG. 8A.

FIG. 8D is a cross-sectional view of a fixing member in another embodiment of the present disclosure.

FIG. 8E is a perspective view of the fixing member illustrated in FIG. 8D.

FIG. 8F is a rear perspective view of the fixing member illustrated in FIG. 8D.

FIG. 8G is a cross-sectional view of a fixing member in another embodiment of the present disclosure.

FIG. 8H is a perspective view of the fixing member illustrated in FIG. 8G.

FIG. 8I is a rear perspective view of the fixing member illustrated in FIG. 8G.

FIG. 8J is a cross-sectional view of a fixing member according to still another embodiment of the present disclosure.

FIG. 8K is a perspective view of the fixing member illustrated in FIG. 8J.

FIG. 8L is a rear perspective view of the fixing member illustrated in FIG. 8J.

FIG. 9 is an enlarged partial cross-sectional view of the fixing member and a frame in the semiconductor package illustrated in FIG. 1, showing their joints as viewed from above.

FIG. 10 is an enlarged view of main part A illustrated in FIG. 9.

FIG. 11 is an external perspective view of a semiconductor package and a semiconductor apparatus according to another embodiment of the present disclosure.

FIG. 12 is an exploded perspective view of the semiconductor package and the semiconductor apparatus illustrated in FIG. 11.

FIG. 13 is a perspective view of the semiconductor package illustrated in FIG. 11.

FIG. 14 is a plan view of the semiconductor package illustrated in FIG. 11.

FIG. 15 is a perspective view of a body in the semiconductor package illustrated in FIG. 11.

FIG. 16A is a perspective view of a fixing member in the semiconductor package illustrated in FIG. 11.

FIG. 16B is a rear perspective view of the fixing member illustrated in FIG. 16A.

FIG. 16C is a cross-sectional view taken along line Y3-Y3 in FIG. 16A.

FIG. 17 is a cross-sectional view of the semiconductor package taken along line X2-X2 in FIG. 13.

FIG. 18 is an enlarged view of main part B illustrated in FIG. 17.

FIG. 19 is an enlarged view of main part B illustrated in FIG. 17 for a semiconductor package according to still another embodiment of the present disclosure.

### DESCRIPTION OF EMBODIMENTS

Recent small devices incorporate known small semiconductor packages for semiconductor devices such as ICs, light-emitting diodes, piezoelectric elements, or quartz oscillators. Other known semiconductor packages can contain optical semiconductor devices such as laser diodes or photodiodes.

Patent Literature 1 describes a semiconductor package that includes a fixing member and a body containing a mount on which an optical semiconductor device is mountable. The body has a through-hole in its side surface. The fixing member is placed in the through-hole and fixed with a bond. An optical component such as an optical fiber is welded to the fixing member using, for example, a laser.

With the technique described in Patent Literature 1, a portion of the fixing member, to which the optical fiber is fixed, is received in the through-hole in the side surface of the body. The received portion of the fixing member is circular, and the through-hole is also circular. The received portion of the fixing member is joined to the through-hole portion with a bond.

In such a semiconductor package, the circular portion of the fixing member is joined to the circular through-hole portion of the body with a bond without a reference plane. Thus, positioning the fixing member may be difficult, possibly causing misalignment in the optical axis. Structure of Semiconductor Package and Semiconductor Apparatus

Embodiments of the present disclosure will now be described by way of example with reference to the drawings. Although the semiconductor package and the semiconductor apparatus may have any of their faces being upward or downward, they are herein defined using the orthogonal xyz coordinate system with the positive z-direction being upward for ease of explanation. A first direction herein refers to, for example, y-direction in the drawings. A second direction refers to a direction orthogonal to the first direction in a plan view, and refers to, for example, x-direction in the drawings. A third direction refers to a direction orthogonal to the first direction and the second direction in a plan view, and refers to, for example, z-direction in the drawings.

### First Embodiment

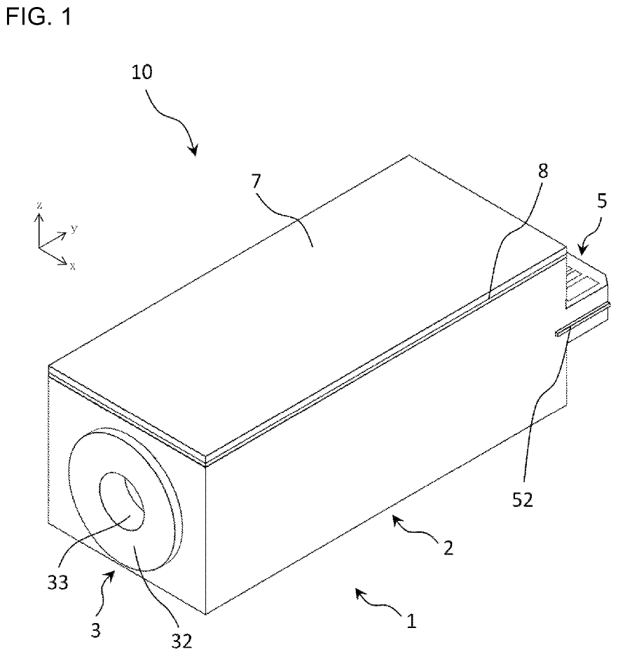

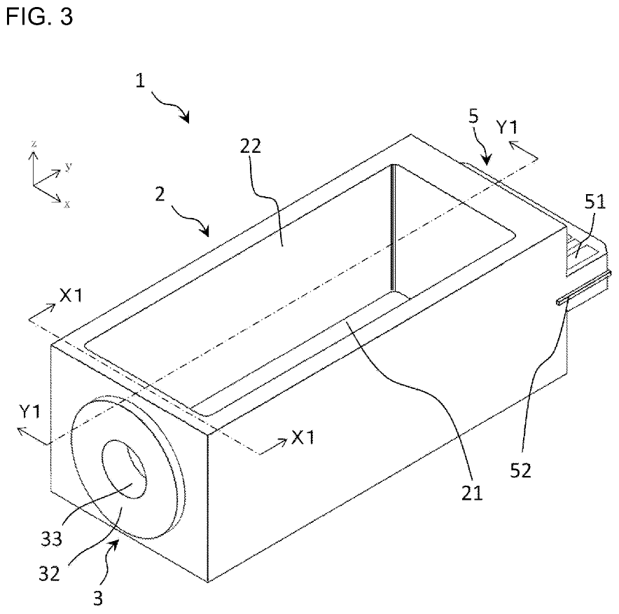

A semiconductor package 1 and a semiconductor apparatus 10 including the semiconductor package 1 according to a first embodiment of the present disclosure will be described with reference to FIGS. 1 to 10.

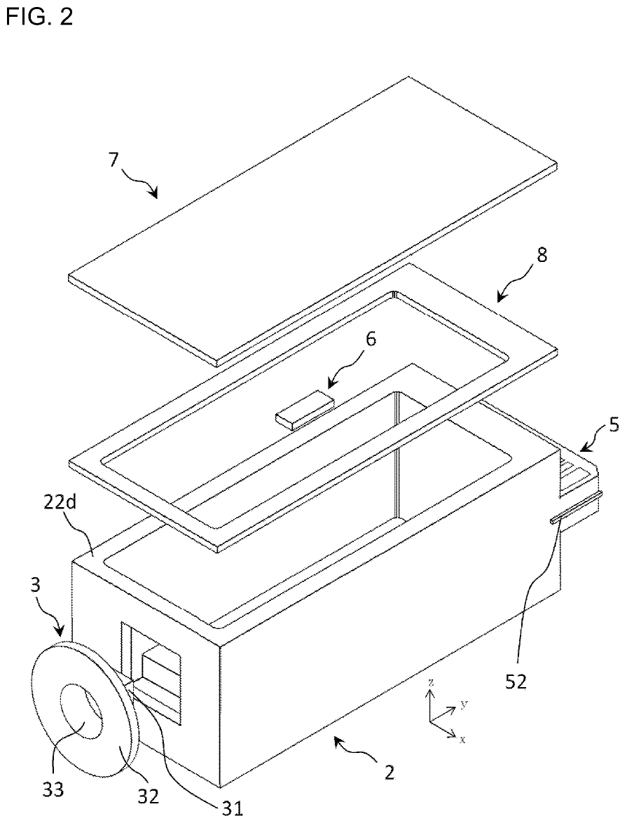

As illustrated in FIGS. 1 and 2, the semiconductor apparatus 10 includes a semiconductor device 6, the semiconductor package 1, and a lid 7. The semiconductor apparatus 10 may further include a seal ring 8.

The semiconductor device 6 converts, for example, an optical signal to an electrical signal or an electrical signal to an optical signal. As illustrated in FIG. 2, the semiconductor device 6 is accommodated in the semiconductor package 1.

Examples of the semiconductor device 6 include an optical semiconductor device such as a semiconductor laser diode (LD) or a photodiode (PD), a semiconductor integrated circuit, and a sensor device such as an optical sensor. The semiconductor device 6 may be made of, for example, a semiconductor material such as gallium arsenide or gallium nitride.

The semiconductor package 1 protects the semiconductor device 6 from the external environment. The semiconductor package 1 includes at least a body 2 that accommodates the semiconductor device 6, a fixing member 3 joined to the body 2, a bond 4 joining the body 2 and the fixing member 3, and an input-output terminal 5.

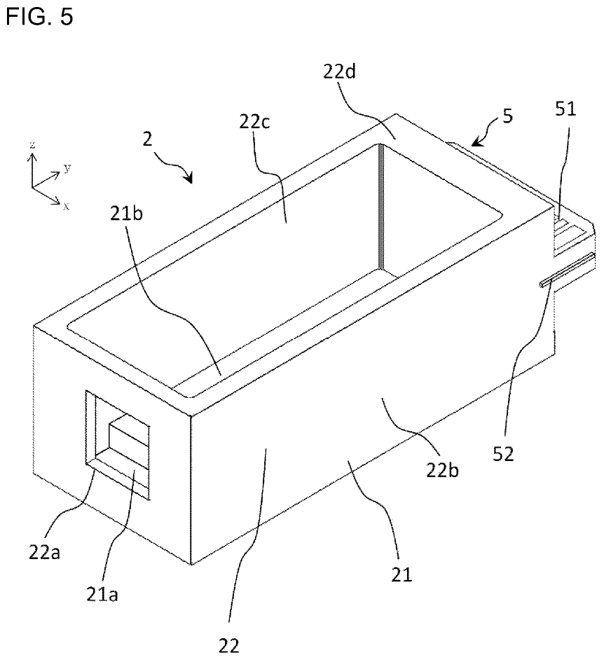

The body 2 includes a base 21 and a frame 22 as illustrated in FIG. 5. The base 21 in the body 2 includes a first upper surface 21a. The frame 22 in the body 2 includes an opening portion 22a, an outer side surface 22b, an inner side surface 22c, and a second upper surface 22d. The frame 22 is located on the first upper surface 21a.

The semiconductor device 6 is mounted on the base 21 in the body 2. The base 21 is, for example, rectangular in a plan view, with the first upper surface 21a being a surface on which the semiconductor device 6 is mounted.

The base 21 dissipates heat generated by the semiconductor device 6 in the semiconductor package 1 out of the semiconductor package 1. The base 21 is rectangular in a plan view in the present embodiment, but may be in any other shape, such as polygonal or elliptical, on which the semiconductor device 6 is mountable. The base 21 may have a length of, for example, about 5 to 50 mm inclusive on each side in a plan view.

Examples of the material for the base 21 include a metal such as copper, iron, tungsten, molybdenum, nickel, or cobalt, and an alloy containing any of these metals. In this case, the base 21 may be a metal plate, or a stack of multiple metal plates. The base 21 made of any of the above metals may include its surface coated with a plating layer of, for example, nickel or gold using electroplating or electroless plating to reduce oxidative corrosion.

The base 21 made of any of the above metals may be obtained by processing an ingot of any of the above metals into a predetermined shape using metalworking such as rolling, punching, or cutting.

The main component of the base 21 may be, for example, a ceramic material such as sintered aluminum oxide, sintered mullite, sintered silicon carbide, sintered aluminum nitride, sintered silicon nitride, or glass ceramic. When the main component of the base 21 is the ceramic material, the first upper surface 21a of the base 21 may undergo wiring by sintering a metal paste containing a metal such as molybdenum or manganese to transmit a high frequency signal or wiring with a thin film deposition method such as vapor deposition or sputtering. The main component in the present disclosure refers to at least a component with the highest content, for example, 90% or more.

The first upper surface 21a of the base 21 may include a step (e.g., a submount) for mounting the semiconductor device 6. The step may be used to mount the semiconductor device 6.

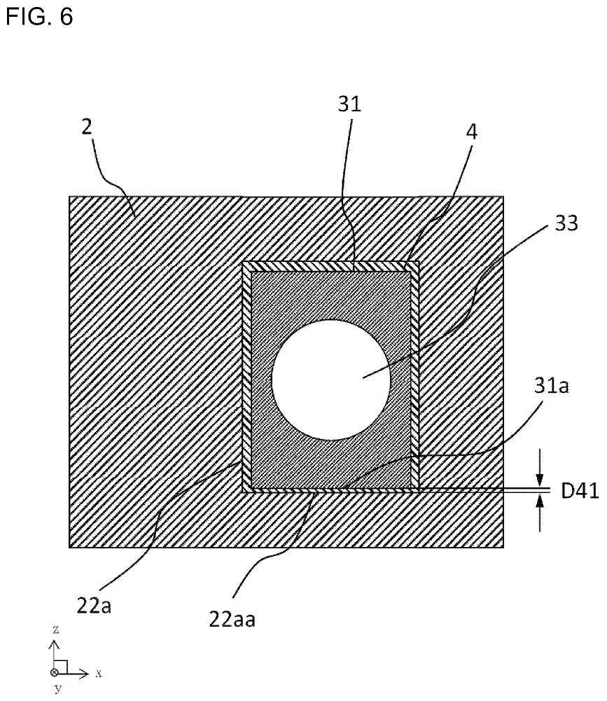

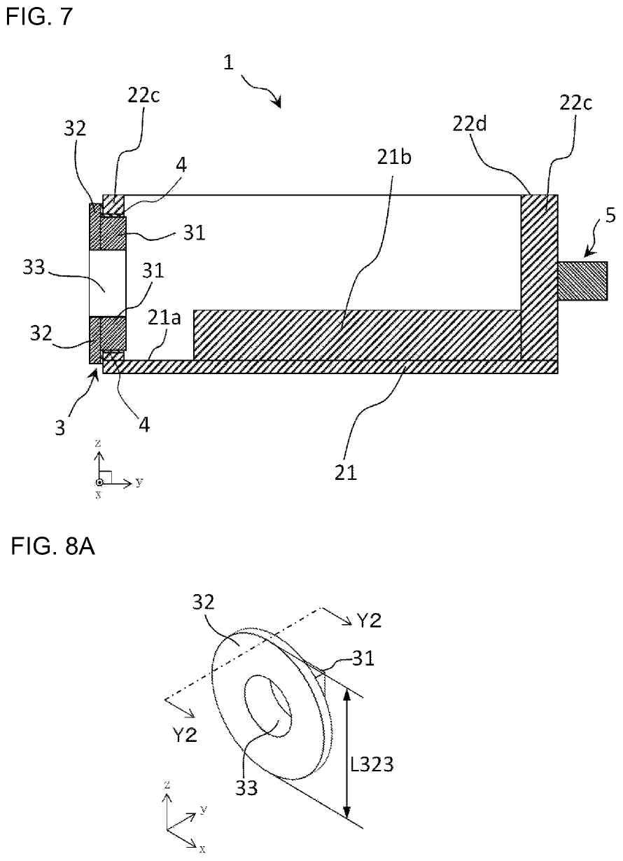

The base 21 made of a ceramic material may include the step as its integral portion. When the step is integral with the base 21, as illustrated in FIG. 7, the base 21 may include, on the first upper surface 21a, a protrusion 21b on which the semiconductor device 6 is mountable.

The frame 22 in the body 2 is located on the first upper surface 21a of the base 21 as illustrated in FIGS. 2, 3, and 5. The frame 22 protects the semiconductor device 6 located inside the frame 22 in a plan view. In other words, the frame 22 surrounds the semiconductor device 6 in a plan view. The frame 22 may extend along the outer edges of the first upper surface 21a or may be located inward from the outer edges of the first upper surface 21a. The frame 22 may extend along part of the outer edges of the first upper surface 21a of the base 21. In other words, the frame 22 may include an open portion.

Examples of the material for the frame 22 include a metal such as coper, iron, tungsten, molybdenum, nickel, or cobalt, and an alloy containing any of these metals. Other examples of the material for the frame 22 include an insulating material that may be, for example, a ceramic material such as sintered aluminum oxide, sintered mullite, sintered silicon carbide, sintered aluminum nitride, sintered silicon nitride, or glass ceramic.

The frame 22 may be joined to the base 21 with, for example, a brazing material. The brazing material may be, for example, silver, copper, gold, aluminum, or magnesium, and may contain additives such as nickel, cadmium, or phosphorus. The frame 22 and the base 21 made of the same material may be integral with each other. This eliminates the process of joining the base 21 and frame 22 using a bond.

The opening portion 22a of the frame 22 is open through the frame 22 in the first direction from the outer side surface 22b to the inner side surface 22c, as illustrated in FIG. 5. As illustrated in FIG. 6, in a cross-sectional view taken along a plane intersecting with the first direction, the opening portion 22a at least partially includes a first linear portion 22aa. Being intersecting herein refers to not being parallel. The first direction refers to, for example, y-direction in the drawings.

The opening portion 22a may be polygonal in a cross-sectional view taken along a plane intersecting with the first direction. As illustrated in FIG. 6, when the opening portion 22a is rectangular in a cross-sectional view taken along a plane intersecting with the first direction, one of the four sides may be the first linear portion 22aa.

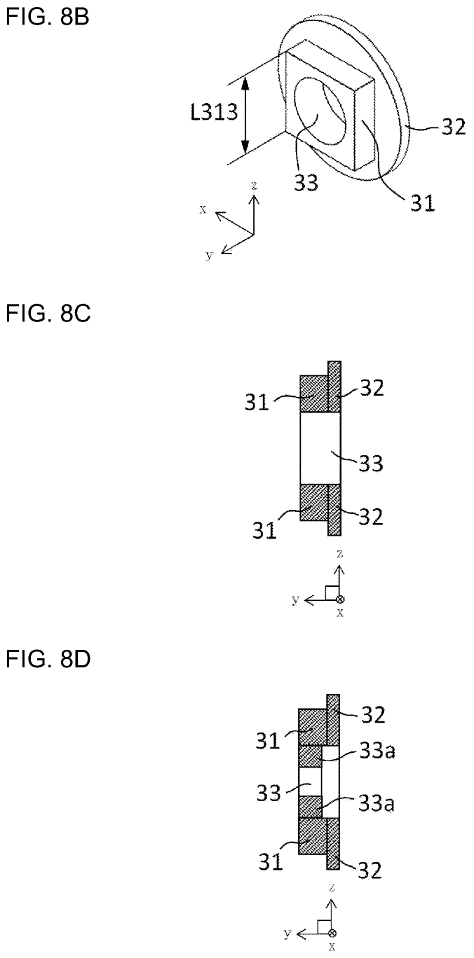

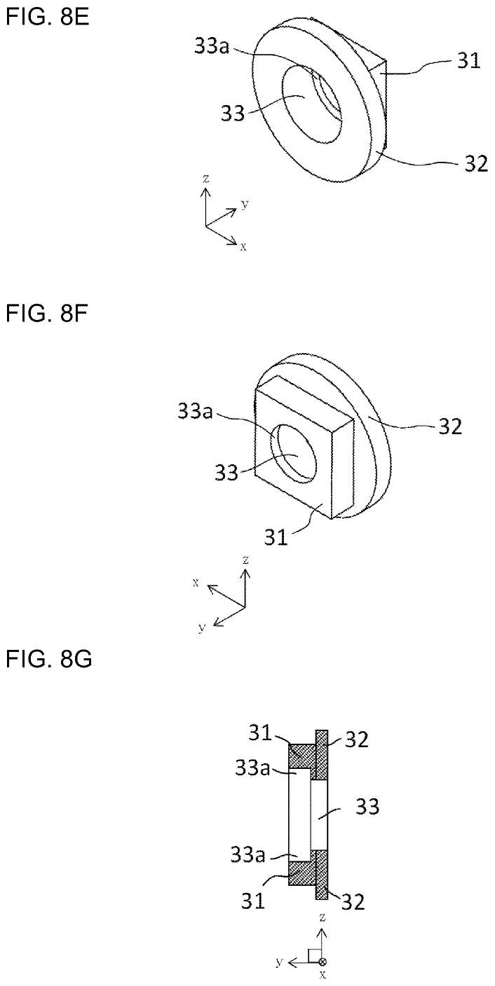

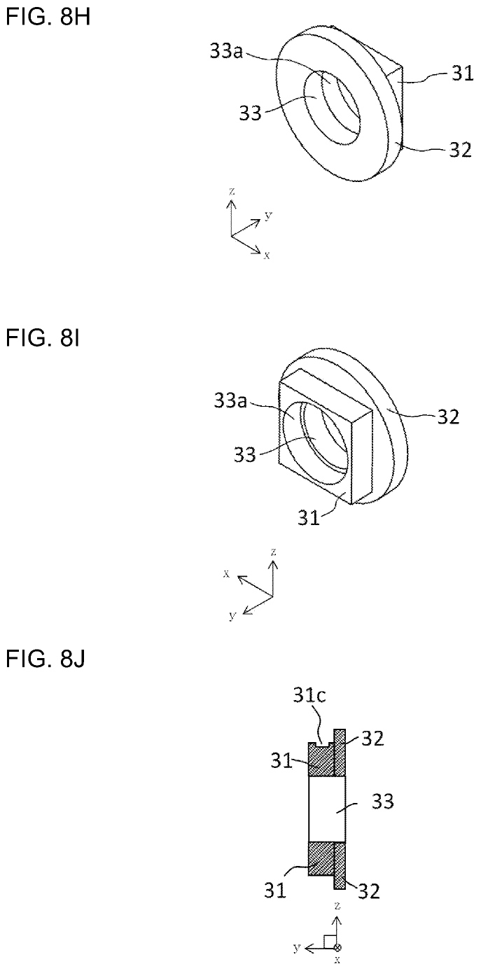

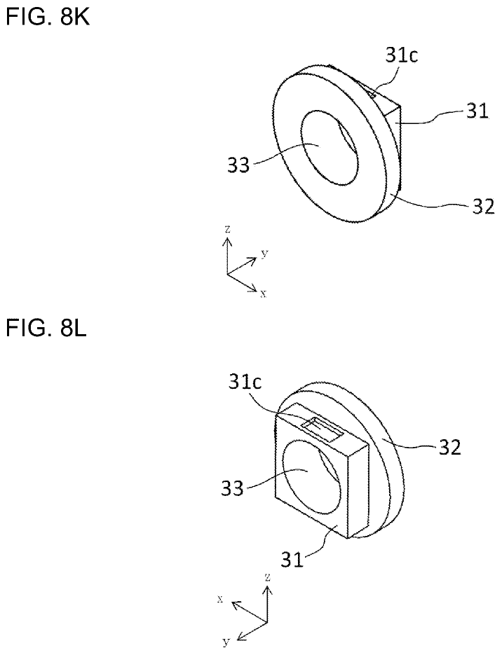

As illustrated in FIGS. 8A to 8C, the fixing member 3 includes a first portion 31 located in the opening portion 22a of the frame 22, a second portion 32 continuous with the first portion 31 and located on the outer side surface 22b of the frame 22, and a through-hole 33 extending through the first portion 31 and the second portion 32 in the first direction. An optical component such as a lens or an optical fiber is fixed to the fixing member 3.

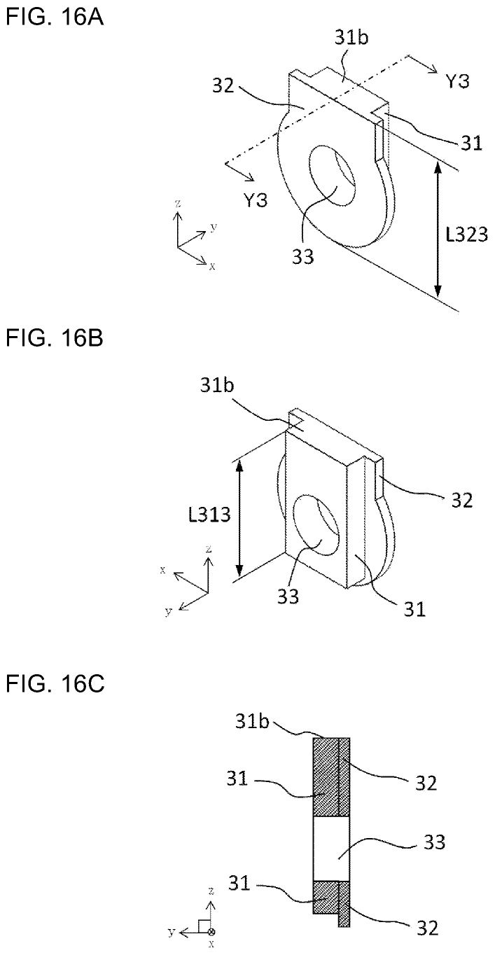

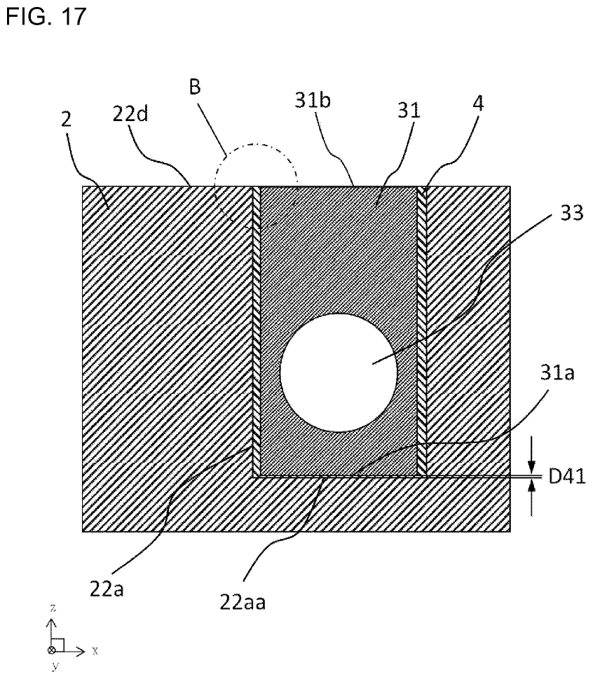

Examples of the material for the fixing member 3 include a metal such as copper, iron, tungsten, molybdenum, nickel, or cobalt, and an alloy containing any of these metals. The fixing member 3 may be fabricated by, for example, processing an ingot obtained by solidifying a molten metal cast in a mold into a predetermined shape using metalworking such as rolling or punching. The predetermined shape is, as in the example in FIGS. 16A to 16C, a shape with the second portion 32 being a combination of a circle and a rectangle, and the first portion 31 being rectangular as viewed laterally in the first direction.

The first portion 31 of the fixing member 3 is joined to the opening portion 22a of the frame 22 with a bond 4. As illustrated in FIG. 6, in a cross-sectional view taken along a plane intersecting with the first direction, the first portion 31 includes a second linear portion 31a facing the first linear portion 22aa of the opening portion 22a. The thickness of the bond 4 (D41) may be smallest between the first linear portion 22aa and the second linear portion 31a. In this case, the thickness of a portion of the bond 4 between the first linear portion 22aa and the second linear portion 31a may be smallest, or the thickness of the full portion of the bond 4 between the first linear portion 22aa and the second linear portion 31a may be smallest. This allows the first linear portion 22aa and the second linear portion 31a to serve as reference planes for optical axis alignment.

As illustrated in FIG. 6, in a cross-sectional view taken along a plane intersecting with the first direction, the first portion 31 of the fixing member 3 may have a shape conforming to the opening portion 22a. In this case, the joint area between the first portion 31 of the fixing member 3 and the opening portion 22a is larger than the joint area with the first portion 31 of the fixing member 3 having a shape not conforming to the opening portion 22a. This increases the joint strength between the fixing member 3 and the body 2. The shape of the first portion 31 conforming to the opening portion 22a herein may be other than being completely similar to the opening portion 22a. For example, either the first portion 31 or the opening portion 22a may have a manufacturing error. For example, the opening portion 22a may have a rectangular shape whereas the first portion 31 may have a rectangular shape with at least one corner partially trimmed. The distance between the opening portion 22a and the facing sides of the first portion 31 may be nonuniform in some portions. The first portion 31 may have a size of 2×2 to 10×10 mm as viewed laterally in the first direction.

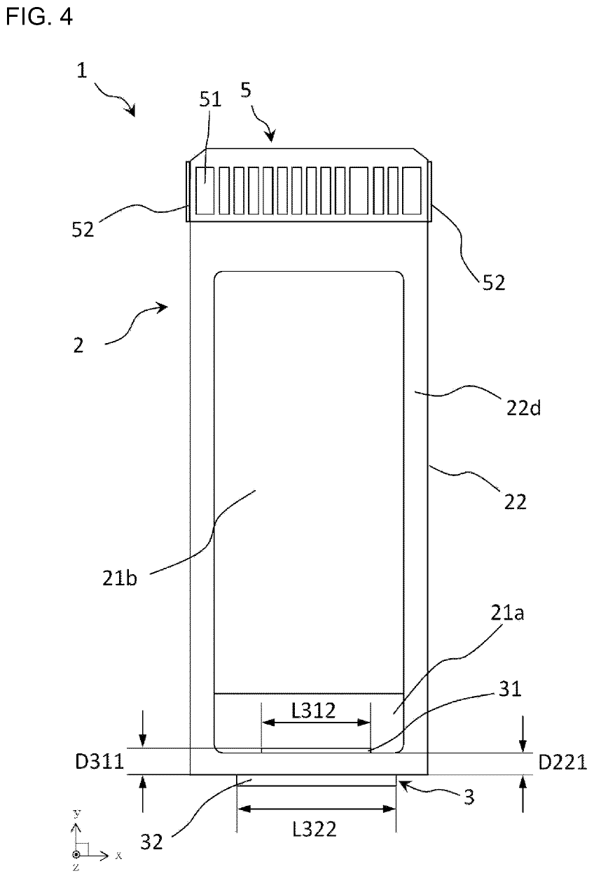

As illustrated in FIG. 4, the fixing member 3 may have, in a plan view, a length L312 of the first portion 31 in the second direction smaller than a length L322 of the second portion 32 in the second direction. This increases the area of contact or the area of contact through the bond 4 between the second portion 32 and the frame 22, thus increasing the joint strength between the fixing member 3 and the frame 22. The length L312 of the first portion 31 in the second direction may be, for example, 2 to 10 mm inclusive. The length L322 of the second portion 32 in the second direction may be, for example, 2 to 15 mm inclusive.

As illustrated in FIGS. 8A to 8C, the fixing member 3 may have a length L313 of the first portion 31 in the third direction smaller than a length L323 of the second portion 32 in the third direction. This increases the area of contact or the area of contact through the bond 4 between the second portion 32 and the frame 22, thus increasing the joint strength between the fixing member 3 and the frame 22. The length L313 of the first portion 31 in the third direction may be, for example, 2 to 10 mm inclusive. The length L323 of the second portion 32 in the third direction may be, for example, 2 to 15 mm inclusive.

In at least one of a cross-sectional view taken along a plane intersecting with the first direction or a cross-sectional view taken along a plane intersecting with the second direction, the fixing member 3 may include the first portion 31 partially flush with the second portion 32. For example, as in the embodiment described later, the first portion 31 may be partially flush with the second portion 32 in a cross-sectional view taken along a plane intersecting with the first direction, or the first portion 31 may be partially flush with the second portion 32 both in a cross-sectional view taken along a plane intersecting with the first direction and in a cross-sectional view taken along a plane intersecting with the second direction.

As illustrated in FIGS. 8J to 8L, for example, the first portion 31 of the fixing member 3 may include a recess 31c recessed in at least one of the second direction or the third direction. In this case, the bond 4 between the opening portion 22a and the first portion 31 can be held in the recess 31c. This further increases the joint strength between the fixing member 3 and the body 2.

As illustrated in FIG. 4, the first portion 31 may have a thickness D311 in the first direction larger than a thickness D221 of the frame 22 in the first direction. In this case, the joint area between the opening portion 22a and the first portion 31 is larger than the joint area with the thickness D311 of the first portion 31 in the first direction being smaller than the thickness D221 of the frame 22 in the first direction. This increases the joint strength between the fixing member 3 and the frame 22. In the present embodiment, the thickness D311 of the first portion 31 and the thickness D221 of the frame 22 are each uniform in the second direction, but these thicknesses may be partially smaller. For example, the thickness of the frame 22 may be partially larger around the opening portion 22a of the frame 22 to which the first portion 31 is fixed. When each of the thickness D311 of the first portion 31 in the first direction and the thickness D221 of the frame 22 in the first direction is nonuniform, the minimum thickness of the first portion 31 in the first direction may be larger than the maximum thickness of the frame 22 in the first direction by, for example, 10 to 100 μm inclusive.

The second portion 32 of the fixing member 3 may have any shape as viewed laterally in the first direction. For example, the second portion 32 may be circular, as illustrated in FIGS. 8A and 8B.

The through-hole 33 in the fixing member 3 may be circular, as illustrated in FIGS. 8A to 8C. As illustrated in FIGS. 8D to 8L, a portion of the fixing member 3 defining the through-hole 33 may include a holder 33a recessed or protruding in a cross-sectional view taken along a plane intersecting with the second direction. In this case, the through-hole 33 receives a lens, and the recessed or protruding holder 33a joins the fixing member 3 to the lens. The lens is, for example, made of a light-transmissive material such as glass, a light-transmissive resin, or sapphire. The through-hole 33 in the fixing member 3 may receive and hold, for example, an optical fiber. The through-hole 33 has a diameter of, for example, 1.5 to 5 mm inclusive.

The bond 4 is located between the opening portion 22a of the frame 22 and the first portion 31 of the fixing member 3 to join the opening portion 22a to the first portion 31. As illustrated in FIG. 6, the thickness of the bond 4 is smallest between the first linear portion 22aa and the second linear portion 31a. In other words, the thickness D41 of the bond 4 between the first linear portion 22aa of the opening portion 22a and the second linear portion 31a of the first portion 31 is smaller than the thickness of the bond 4 other than between the first linear portion 22aa of the opening portion 22a and the second linear portion 31a of the first portion 31. In other words, the bond 4 has the smallest thickness between the second linear portion 31a of the first portion 31 and the first linear portion 22aa. The thickness of the bond 4 herein refers to the thickness in a cross-sectional view taken along a plane intersecting with the first direction.

In the present embodiment, as illustrated in FIG. 6, the thickness D41 of the bond 4 located between the first linear portion 22aa and the second linear portion 31a is uniform along the first linear portion 22aa. In this case, the plane including the first linear portion 22aa and the plane including the second linear portion 31a can serve as reference planes. This facilitates positioning of the fixing member 3 relative to the opening portion 22a of the body 2, thus reducing the likelihood of optical axis misalignment. As described above, the thickness D41 of the bond 4 may not be uniform along the first linear portion 22aa. In this case, the bond 4 located between the first linear portion 22aa and the second linear portion 31a may partially have the smallest thickness.

The bond 4 may be, for example, solder, a brazing material, glass, or a resin material. The brazing material may be, for example, a silver brazing material, which has high heat resistance and joint strength among other bonds.

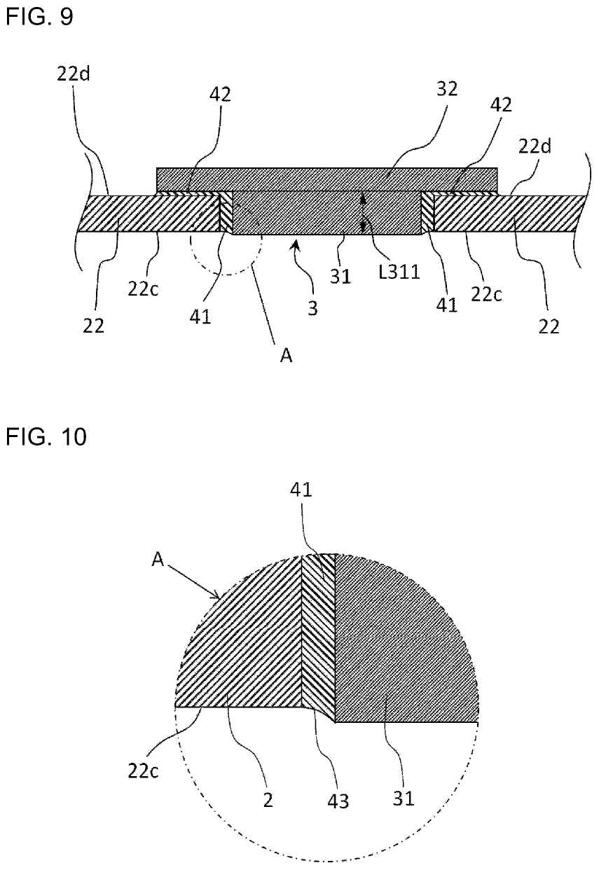

As illustrated in FIG. 9, the bond 4 may include a first section 41 located between the first portion 31 of the fixing member 3 and the opening portion 22a, and a second section 42 continuous with the first section 41 and located between the second portion 32 of the fixing member 3 and the outer side surface 22b. In other words, the opening portion 22a and the first portion 31 are joined by the first section 41 of the bond 4, and the second portion 32 and the outer side surface 22b are joined by the second section 42 located continuously with the first section 41 of the bond 4. This further increases the joint area between the fixing member 3 and the body 2, thus increasing the joint strength between the fixing member 3 and the body 2. In this case, for example, the area of the second portion 32 as viewed laterally in the first direction may be larger than the area of the opening portion 22a.

When the thickness D311 of the first portion 31 in the first direction is larger than the thickness D221 of the frame 22 in the first direction, the bond 4 may include a curved end portion 43 adjacent to the inner side surface 22c, as illustrated in FIG. 10. In other words, the bond 4 includes a fillet at the joint between the fixing member 3 and the body 2. This increases the joint strength of the fixing member 3 to the body 2. A fillet herein refers to a shape with a chamfered surface.

The input-output terminal 5 may be a stack of multiple layers including a first wiring layer 51 and a second wiring layer 52. The input-output terminal 5 is located on the outer side surface 22b of the frame 22 and separate from the opening portion 22a of the frame 22. For example, when the base 21 is rectangular in a plan view, the input-output terminal 5 may be located on a side of the outer side surface 22b of the frame 22 other than the side with the opening portion 22a. The first wiring layer 51 and the second wiring layer 52 transmit electrical signals between the semiconductor device 6 and an external circuit board. As illustrated in FIG. 4, the first wiring layer 51 may be exposed on the upper surface of the input-output terminal 5 in a plan view.

Examples of the materials for the multiple layers in the input-output terminal 5 include insulating materials including ceramic materials such as sintered aluminum oxide, sintered mullite, sintered silicon carbide, sintered aluminum nitride, sintered silicon nitride, and sintered glass ceramic.

A method for fabricating the input-output terminal 5 will now be described. First, green sheets corresponding to the multiple layers in the input-output terminal 5 are prepared. Each green sheet is processed into a predetermined shape using a tool such as a laser, a punch, or a cutter to obtain multiple layers yet to be fired. The uncured multiple layers yet to be fired then undergo, for example, wiring by sintering a metal paste containing a metal such as molybdenum or manganese to transmit a high frequency signal or wiring with a thin film deposition method such as vapor deposition or sputtering. The first wiring layer 51 and the second wiring layer 52 are thus obtained. Subsequently, the multiple layers including the first wiring layer 51 and the second wiring layer 52 are press-joined and co-fired in a stacked state.

As illustrated in FIG. 4, the input-output terminal 5 may include the second wiring layer 52 larger than the frame 22 in a plan view. The second wiring layer 52 being larger than the frame 22 herein refers to the second wiring layer 52 including a portion protruding from the frame 22 by, for example, 0.05 to 2 mm inclusive in the second direction in a plan view. Thus, when the second wiring layer 52 includes wiring such as a high-frequency signal line, the protruding portion of the second wiring layer 52 can serve as a reference plane in stacking the layers. This reduces stacking misalignment in fabricating the input-output terminal 5 and also reduces misalignment between the wiring layers and the fixing member 3.

The input-output terminal 5 may be joined to the frame 22 with a brazing material or may be integral with the frame 22.

Lead terminals may also be connected to the first wiring layer 51 in the input-output terminal 5. The lead terminals are members for electrical connection with, for example, an external electrical circuit board. The lead terminals may be connected to the first wiring layer 51 with a brazing material.

The seal ring 8 joins the frame 22 and the lid 7. As illustrated in FIG. 2, the seal ring 8 is located on the second upper surface 22d of the frame 22 and surrounds the semiconductor device 6 in a plan view or in a plan view in a transparent manner. Examples of the material for the seal ring 8 include metals such as iron, copper, silver, nickel, chromium, cobalt, molybdenum, and tungsten, and alloys of more than one of these metals.

The lid 7 is located on the second upper surface 22d of the frame 22 and protects the semiconductor device 6 together with the frame 22. The lid 7 is joined to the frame 22 with the seal ring 8 located on the second upper surface 22d of the frame 22 to seal the semiconductor package 1, as illustrated in FIGS. 1 and 2. The lid 7 may be made of, for example, a metal. Examples of the material for the lid 7 include metals such as iron, copper, silver, nickel, chromium, cobalt, molybdenum, and tungsten, and alloys of more than one of these metals. When no seal ring 8 is located on the second upper surface 22d of the frame 22, the lid 7 may be joined with a bonding material such as solder, a brazing material, glass, or a resin boding material.

### Methods for Manufacturing Semiconductor Package and Semiconductor Apparatus 10

Methods for manufacturing the semiconductor package 1 and the semiconductor apparatus 10 according to the first embodiment will now be described. The present disclosure is not limited to the embodiments described below.

(a) Multiple green sheets are prepared first. More specifically, for example, a ceramic powder such as a powder of boron nitride, aluminum nitride, silicon nitride, silicon carbide, or beryllium oxide is mixed with, for example, an organic binder, a plasticizer, or a solvent to obtain a mixture. The mixture is formed into layers as multiple green sheets. The multiple green sheets described above are then processed using, for example, a die to prepare multiple first green sheets in the outline shape of the base 21 in a plan view and multiple second green sheets in the outline shape of the frame 22 in a plan view, as illustrated in FIG. 4. Some of the second green sheets are formed with a cutout in the outline shape of the frame 22 in a plan view at a position corresponding to the opening portion 22a of the frame 22.

When the input-output terminal 5 is integral with the frame 22, some of the second green sheets are formed into an outline shape combining the frame 22 and the input-output terminal 5. In this process, for example, vias may be formed in the multiple first green sheets and the multiple second green sheets using, for example, a die or a laser.

In the example described above, the material for the base 21 is the same ceramic material as for the frame 22. When either the base 21 or the frame 22 is made of a metal, an ingot obtained by casting and solidifying a molten metal in a mold is formed into a predetermined shape using, for example, metalworking.

(b) A high-melting-point metal powder, such as a tungsten or molybdenum powder, is prepared and is mixed with, for example, an organic binder, a plasticizer, or a solvent to prepare a metal paste. A predetermined pattern is then printed with the metal paste on each of the multiple first green sheets and the multiple second green sheets to form wiring. The metal paste may contain glass or a ceramic material to increase the joint strength with the body 2.

(c) The multiple first green sheets and the multiple second green sheets are stacked with their outer edges aligned to form a stack of green sheets. In some embodiments, the wiring may be formed by printing a predetermined pattern with the metal paste after forming the stack of green sheets.

(d) The stack of green sheets is fired to sinter the multiple first and second green sheets to obtain the body 2 including the base 21 and the frame 22 joined together. To obtain the input-output terminal 5 integral with the frame 22, the body 2 including the frame 22 also joined with the input-output terminal 5 is obtained. When either the material for the base 21 or the material for the frame 22 is a metal, the base 21 and the frame 22 are joined using, for example, a brazing material to obtain the body 2.

(e) The fixing member 3 formed in a predetermined shape using a metal is joined to the frame 22 with the bond 4 to obtain the semiconductor package 1. The semiconductor device 6 is then mounted on the first upper surface 21a of the base 21, and the lid 7 is joined to the second upper surface 22d of the frame 22 to obtain the semiconductor apparatus 10. As illustrated in FIG. 2, the lid 7 may be joined with the seal ring 8 located on the second upper surface 22d of the frame 22.

### Second Embodiment

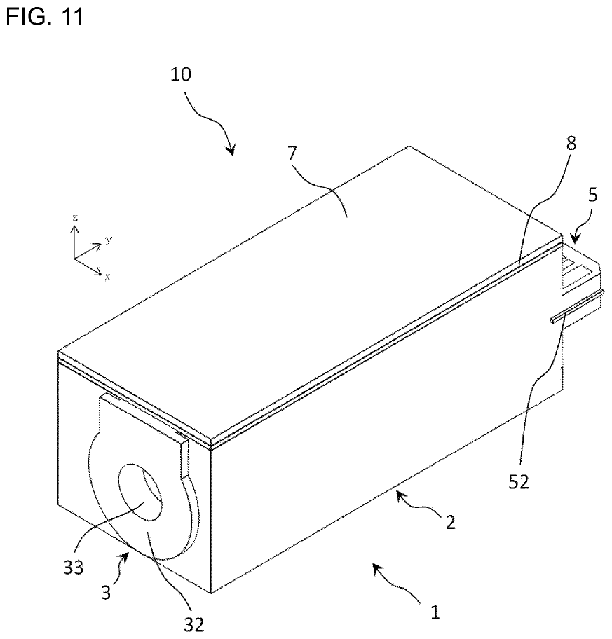

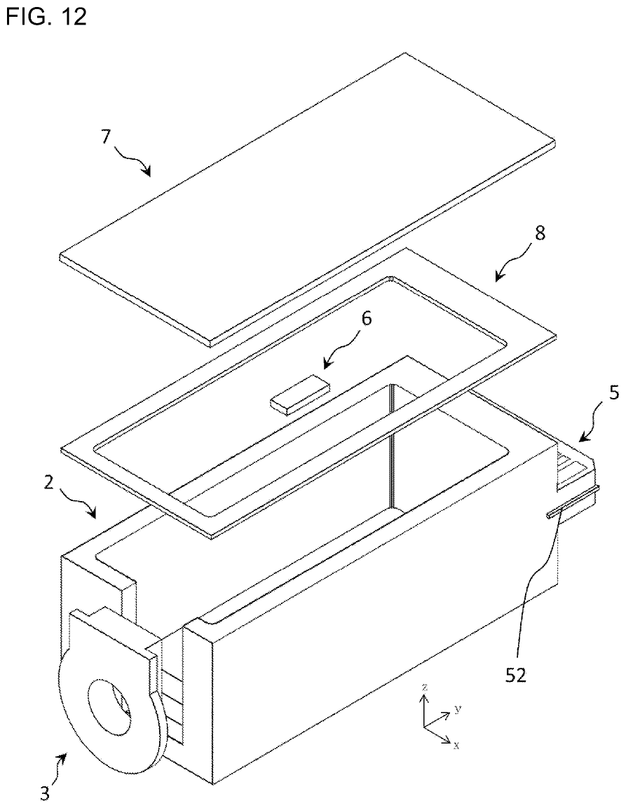

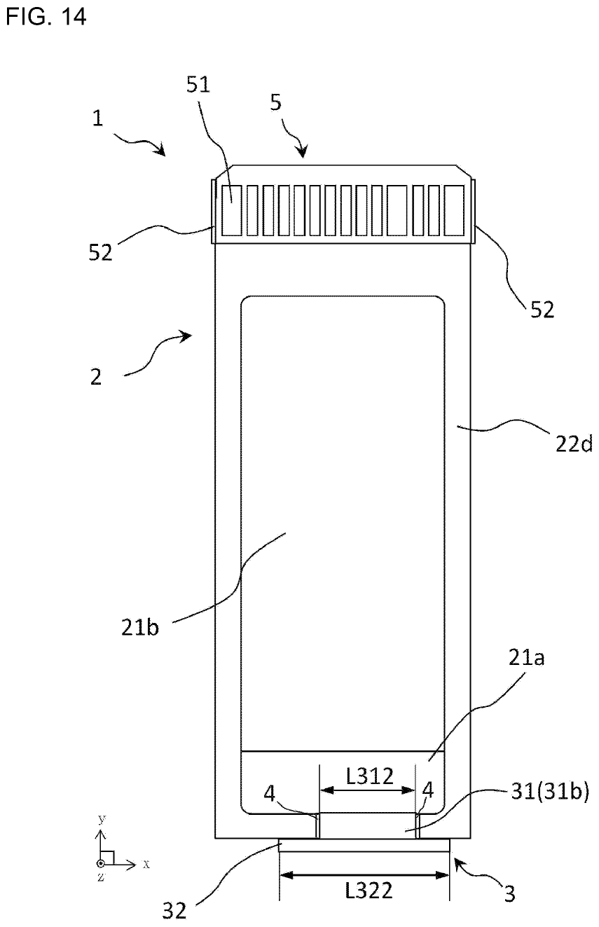

A semiconductor package 1 according to a second embodiment of the present disclosure will now be described with reference to FIGS. 11 to 19.

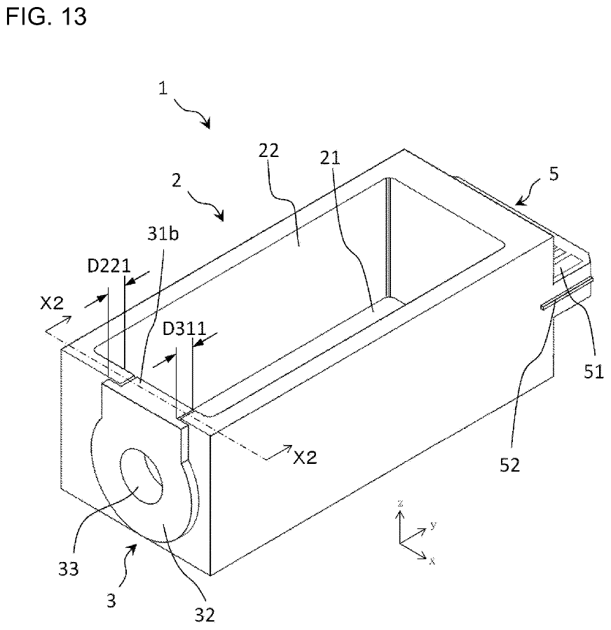

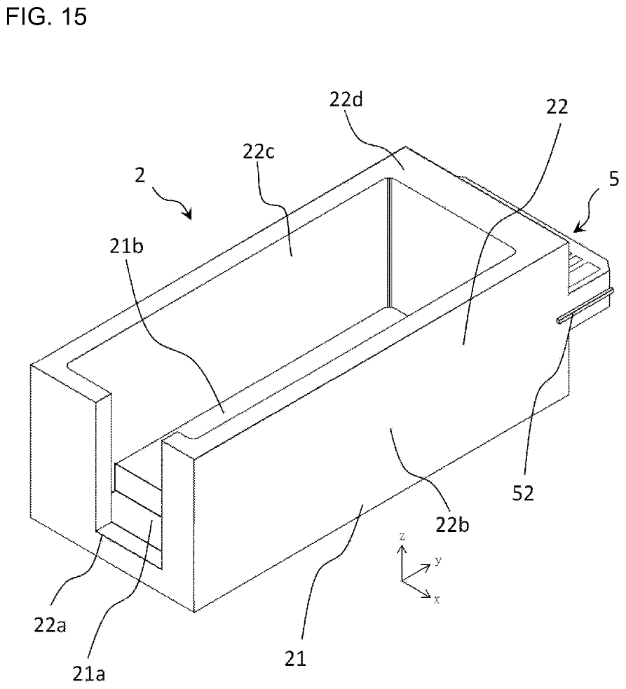

In the present embodiment, the components different from those in the first embodiment are described. As illustrated in FIGS. 16A to 16C, the first portion 31 of the fixing member 3 includes a third upper surface 31b. The opening portion 22a of the frame 22 reaches the second upper surface 22d of the frame 22, as illustrated in FIG. 15. Additionally, the third upper surface 31b of the first portion 31 is flush with the second upper surface 22d of the frame 22, as illustrated in FIGS. 13 and 17. When the lid 7 or the seal ring 8 is located on the second upper surface 22d of the frame 22, the lid 7 or the seal ring 8 is fixed to the third upper surface 31b of the fixing member 3 with a bonding material. This increases the joint area between the first portion 31 and the opening portion 22a, thus further increasing the joint strength between the fixing member 3 and the body 2. When the body 2 is made of a ceramic material, the structure can eliminate a ceramic layer above the opening portion 22a, reducing the likelihood that a ceramic material above the opening portion 22a warps and deforms the body 2.

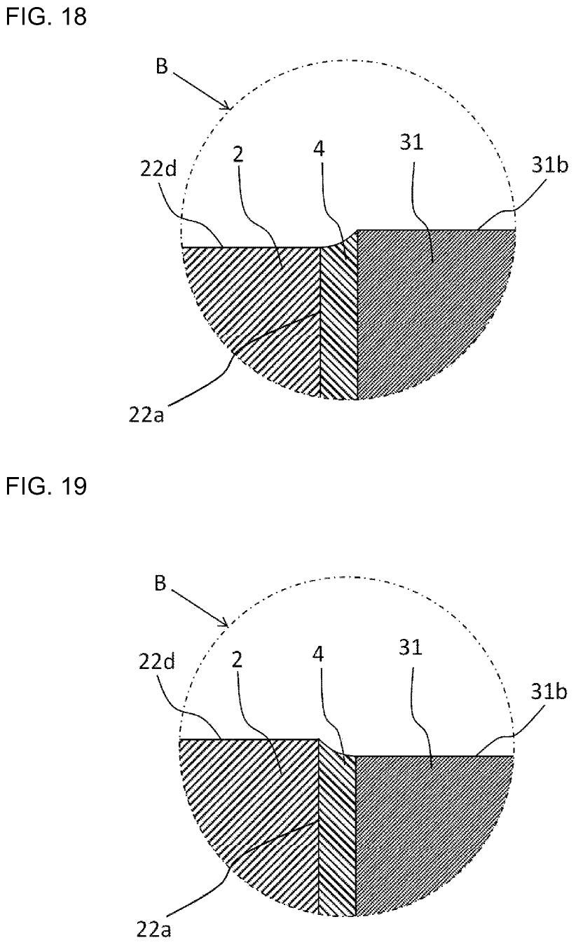

The third upper surface 31b being flush with the second upper surface 22d herein refers to the two surfaces being completely flush with each other and also to a structure with a manufacturing error in which the third upper surface 31b of the first portion 31 is located, for example, about 0.1 mm above the second upper surface 22d of the frame 22 in a cross-sectional view taken along a plane intersecting with the first direction, as illustrated in FIG. 18. As illustrated in FIG. 19, the structure may also allow a manufacturing error in which the third upper surface 31b of the first portion 31 is located, for example, about 0.1 mm below the second upper surface 22d of the frame 22 in a cross-sectional view taken along a plane intersecting with the first direction. This allows the bond 4 to be held on the third upper surface 31b of the first portion 31 when the seal ring 8 or the lid 7 is joined as illustrated in FIG. 11, thus improving airtightness.

The body 2 made of a ceramic material herein may contain, as its material, substances unavoidable in the manufacture other than the ceramic material.

The semiconductor package 1 according to the present embodiment may be fabricated by, for example, changing the number of layers of the second green sheets with a cutout in a portion of the outline shape of the frame 22 in a plan view with the manufacturing method described above.

The present disclosure is not limited to the first and second embodiments and the examples described above, and may be changed variously without departing from the spirit and scope of the present disclosure.

For example, the opening portion 22a may have a shape combining the first linear portion 22aa and a circular arc.

In the second embodiment, the fixing member 3 may include a holder 33a recessed or protruding in a cross-sectional view taken along a plane intersecting with the second direction.

The input-output terminal 5 may be stepped as viewed laterally in the second direction. In other words, the input-output terminal 5 may have a shape with two steps as viewed laterally in the second direction. In this case, the first wiring layer 51 may be located on the upper surface of the upper step, and the second wiring layer 52 may be located on the upper surface of the lower step. The second wiring layer 52 may extend in the first direction, the second direction, or both from the periphery of the frame 22 in a plan view, or the second wiring layer 52 may be a wiring layer that is different from the first wiring layer 51 described above and is exposed in a plan view.

In one or more embodiments of the present disclosure, the semiconductor package may be implemented in structures 1 to 18 described below.

(1) A semiconductor package, comprising:
a body including a base and a frame, the base including a first upper surface, the frame being located on the first upper surface and including an inner side surface, an outer side surface, and an opening portion extending through the frame in a first direction from the outer side surface to the inner side surface;
a fixing member including a first portion located in the opening portion, a second portion continuous with the first portion and located on the outer side surface of the frame, and a through-hole extending through the first portion and the second portion in the first direction; and
a bond located between the first portion and the opening portion,
wherein in a cross-sectional view taken along a plane intersecting with the first direction, the opening portion at least partially includes a first linear portion, and the first portion includes a second linear portion facing the first linear portion, and
the bond has a smallest thickness between the first linear portion and the second linear portion in a cross-sectional view taken along a plane intersecting with the first direction.

(2) The semiconductor package according to (1), wherein
the opening portion is polygonal in a cross-sectional view taken along a plane intersecting with the first direction.

(3) The semiconductor package according to (1) or (2), wherein
the first portion has a shape conforming to the opening portion in a cross-sectional view taken along a plane intersecting with the first direction.

(4) The semiconductor package according to any one of (1) to (3), wherein
the frame includes a second upper surface,
the first portion includes a third upper surface,
the opening portion reaches the second upper surface of the frame, and
the third upper surface of the first portion is flush with the second upper surface of the frame.

(5) The semiconductor package according to any one of (1) to (4), wherein
the first portion has a smaller length than the second portion in a second direction orthogonal to the first direction in a plan view.

(6) The semiconductor package according to (5), wherein
the bond includes a first section located between the first portion and the opening portion, and a second section continuous with the first section and located between the second portion and the outer side surface.

(7) The semiconductor package according to (5) or (6), wherein
the first portion has a smaller length than the second portion in a third direction orthogonal to the first direction and the second direction in a cross-sectional view taken along a plane intersecting with the second direction.

(8) The semiconductor package according to any one of (5) to (7), wherein
the first portion is partially flush with the second portion in at least one of a cross-sectional view taken along a plane intersecting with the first direction or a cross-sectional view taken along a plane intersecting with the second direction.

(9) The semiconductor package according to any one of (5) to (8), wherein
the first portion includes a recess recessed in at least one of the second direction or a third direction orthogonal to the first direction and the second direction.

(10) The semiconductor package according to any one of (1) to (9), wherein
the first portion has a larger thickness than the frame in the first direction.

(11) The semiconductor package according to (10), wherein
the bond includes a curved end portion adjacent to the inner side surface in a plan view.

(12) The semiconductor package according to any one of (1) to (11), wherein
the body includes a protrusion on the first upper surface.

(13) The semiconductor package according to any one of (1) to (12), wherein
the body includes an input-output terminal located on the outer side surface and separate from the opening portion, and the input-output terminal includes at least a first wiring layer and a second wiring layer, and
the second wiring layer includes a portion protruding from the frame in a plan view.

(14) The semiconductor package according to any one of (1) to (13), wherein
the opening portion is rectangular and the first portion is rectangular in a cross-sectional view taken along a plane intersecting with the first direction.

(15) The semiconductor package according to any one of (1) to (14), wherein
the frame and the base comprise a same material and are integral with each other.

(16) The semiconductor package according to any one of (1) to (15), wherein
the body comprises a ceramic material.

(17) The semiconductor package according to any one of (1) to (16), wherein
the bond is a resin adhesive.

(18) The semiconductor package according to any one of (1) to (17), wherein
a portion of the fixing member defining the through-hole includes a holder recessed or protruding in a cross-sectional view taken along a plane intersecting with a second direction orthogonal to the first direction as viewed from above.

In one or more embodiments of the present disclosure, the semiconductor apparatus may be implemented in structure 19 described below.

(19) A semiconductor apparatus, comprising:
the semiconductor package according to any one of (1) to (18); and
a semiconductor device mounted on the first upper surface in the semiconductor package.

In one embodiment of the present disclosure, as described above, the semiconductor package has the thickness of the bond between the first linear portion and the second linear portion smaller than the thickness of the bond between other parts of the first portion and the opening portion to use the plane including the first linear portion and the plane including the second linear portion as reference planes. This facilitates positioning of the fixing member relative to the opening portion of the body. Thus, the semiconductor package and the semiconductor apparatus have less optical axis misalignment.

The present disclosure may be embodied in various forms without departing from the spirit or the main features of the present disclosure. The embodiments described above are thus merely illustrative in all respects. The scope of the present disclosure is defined not by the description given above but by the claims. Any variations and alterations contained in the claims fall within the scope of the present disclosure.

### REFERENCE SIGNS

1 semiconductor package
2 body
21 base
21a first upper surface
21b protrusion
22 frame
22a opening portion
22aa first linear portion
22b outer side surface
22c inner side surface
22d second upper surface
D221 thickness of frame in first direction
3 fixing member
31 first portion
31a second linear portion
31b third upper surface
31c recess
D311 thickness of first portion in first direction
L312 length of first portion in second direction
L313 length of first portion in third direction
32 second portion
L322 length of second portion in second direction
L323 length of second portion in third direction
33 through-hole
33a holder
4 bond
41 first section
42 second section
43 end portion
D41 thickness of bond between first linear portion and second linear portion
5 input-output terminal
51 first wiring layer
52 second wiring layer
6 semiconductor device
7 lid
8 seal ring
10 semiconductor apparatus

1. A semiconductor package, comprising:
a body including a base and a frame, the base including a first upper surface, the frame being located on the first upper surface and including an inner side surface, an outer side surface, and an opening portion extending through the frame in a first direction from the outer side surface to the inner side surface;
a fixing member including a first portion located in the opening portion, a second portion continuous with the first portion and located on an outer side surface side of the frame, and a through-hole extending through the first portion and the second portion in the first direction; and
an optical component fixed to the fixing member,
wherein in a cross-sectional view taken along a plane intersecting with the first direction, the opening portion at least partially includes a first linear portion, and the first portion includes a second linear portion facing the first linear portion.

2. The semiconductor package according to claim 1, wherein
the opening portion is polygonal in a cross-sectional view taken along a plane intersecting with the first direction.

3. The semiconductor package according to claim 1, wherein
the first portion has a shape conforming to the opening portion in a cross-sectional view taken along a plane intersecting with the first direction.

4. The semiconductor package according to claim 1, wherein
the frame includes a second upper surface,
the first portion includes a third upper surface,
the opening portion reaches the second upper surface of the frame, and
the third upper surface of the first portion is flush with the second upper surface of the frame.

5. The semiconductor package according to claim 1, wherein
the first portion has a smaller length than the second portion in a second direction orthogonal to the first direction in a plan view.

6. (canceled)

7. The semiconductor package according to claim 45, wherein
the first portion has a smaller length than the second portion in a third direction orthogonal to the first direction and the second direction in a cross-sectional view taken along a plane intersecting with the second direction.

8. The semiconductor package according to claim 45, wherein
the first portion is partially flush with the second portion in at least one of a cross-sectional view taken along a plane intersecting with the first direction or a cross-sectional view taken along a plane intersecting with the second direction.

9. The semiconductor package according to claim 45, wherein
the first portion includes a recess recessed in at least one of the second direction or a third direction orthogonal to the first direction and the second direction.

10. The semiconductor package according to claim 1, wherein
the first portion has a larger thickness than the frame in the first direction.

11. (canceled)

12. The semiconductor package according to claim 1, wherein
the body includes a protrusion on the first upper surface.

13. The semiconductor package according to claim 1, wherein
the body includes an input-output terminal located on the outer side surface and separate from the opening portion, and the input-output terminal includes at least a first wiring layer and a second wiring layer, and
the second wiring layer includes a portion protruding from the frame in a plan view.

14. The semiconductor package according to claim 1, wherein
the opening portion is rectangular and the first portion is rectangular in a cross-sectional view taken along a plane intersecting with the first direction.

15. The semiconductor package according to claim 1, wherein
the frame and the base comprise a same material and are integral with each other.

16. The semiconductor package according to claim 1, wherein
the fixing member comprises a metal.

17. The semiconductor package according to claim 1, wherein
the frame is comprises a metal.

18. The semiconductor package according to claim 1, wherein
a portion of the fixing member defining the through-hole includes a holder recessed or protruding in a cross-sectional view taken along a plane intersecting with a second direction orthogonal to the first direction as viewed from above.

19. A semiconductor apparatus, comprising:
the semiconductor package according to claim 1; and
a semiconductor device mounted on the first upper surface in the semiconductor package.
